(19) United States
(12) Patent Application Publication
(10) Pub. No.: US 2012/0032282 A1
(43) Pub. Date: Feb. 9, 2012

(54) MICROELECTROMECHANICAL SYSTEM (MEMS) CARRIER AND METHOD OF FABRICATING THE SAME

(75) Inventor: Kun-Chen Tsai, Taoyuan (TW)

(73) Assignee: UNIMICRON TECHNOLOGY CORPORATION, Taoyuan (TW)

(21) Appl. No.: 13/198,029

(22) Filed: Aug. 4, 2011

(30) Foreign Application Priority Data
Aug. 6, 2010 (TW) 099126229

(51) Int. Cl. H01L 29/84; H01L 21/02

(52) U.S. Cl. 257/415; 438/50; 257/E29.324; 257/E21.002

(57) ABSTRACT

An MEMS carrier is provided that includes a core board having a first surface and an opposite second surface, a circuit layer formed on the first surface and having a plurality of conductive pads, and a through hole formed through the first and the second surfaces; a carrier layer formed on the second surface of the core board and covering an end of the through hole; a patterned metal layer formed on a portion of the carrier layer that covers the end of the through hole; a solder mask layer formed on the first surface of the core board and the circuit layer, wherein the solder mask layer has a plurality of openings for exposing the conductive pads; and a shielding metal layer disposed on a sidewall of the through hole, the patterned metal layer, and the portion of the carrier layer that covers the end of the through hole. Without the use of a circuit board, the MEMS carrier has reduced height and size.

### BACKGROUND OF THE INVENTION

1. Field of the Invention

This invention relates to carriers and methods of fabricating the same, and, more particularly, to a microelectromechanical system (MEMS) carrier and a method of fabricating the same.

2. Description of Related Art

Nowadays, MEMS devices such as microphones have been broadly used in the mobile communication equipment, audio message device, etc. In order to protect an MEMS device, a cover component is disposed thereon to prevent the MEMS device from being exposed and damaged.

Referring to FIGS. 1A through 1E, cross-sectional diagrams depicting a method of disposing a cover component 1 on an MEMS device according to the prior art are shown.

As shown in FIG. 1A, a core board 10 is provided that has at least a through hole 100 formed through the core board 10, and an adhering layer 12 is formed on a surface of the core board 10.

As shown in FIG. 1B, a carrier layer 13 is adhered to the adhering layer 12, and covers an end of the through hole 100.

As shown in FIG. 1C, a conductive seed-layer 14 is formed on the core board 10, a sidewall of the through hole 100, and the carrier layer 13 in the through hole 100, and a shielding metal layer 15 is then formed on the conductive seed-layer 14 in an electroplating process.

As shown in FIG. 1D, an acoustic hole 130 is formed through the carrier layer 13, the conductive seed-layer 14, and the shielding metal layer 15, and a surface treatment layer 16 is formed on the shielding metal layer 15. The cover component 1 is thus completed.

As shown in FIG. 1E, a circuit board 11 has wire bonding pads 110, and a microelectromechanical system (MEMS) component 31 and an application specific integrated chip (ASIC) 32 are disposed on the circuit board 11. The MEMS component 31 is electrically connected to the ASIC 32 and the wire bonding pad 110 via conducive wires 33. The cover component 1 is mounted on the circuit board 11 to cover the MEMS component 31 and the ASIC 32.

According to the prior art, since the cover component 1 has the shielding metal layer 15 only, without any other functional metal layer, the cover component 1 can provide nothing but a function of covering the MEMS component 31 and the ASIC 32. Consequently, both the MEMS component 31 and the ASIC 32 have to be mounted on the circuit board 11, in order to be covered by the cover component 1. Accordingly, the overall structure has an increased height, which is disadvantageous in miniaturization of electronic products.

Furthermore, since the MEMS component 31 has to be disposed on the circuit board 11, a space S is thus required between the acoustic hole 130 of the cover component 1 and the MEMS 31. As a result, the path of signal received by the MEMS component 31 is prolonged, and the signal stability and transmission speed are reduced.

Hence, how to overcome the drawbacks of the prior art is becoming one of the critical issues in the art.

### SUMMARY OF THE INVENTION

In view of the drawbacks of the prior art mentioned above, it is therefore an objective of this invention to provide an MEMS carrier and a method of fabricating the same that is advantageous in miniaturization of electronic product.

To achieve the aforementioned and other objectives, the present invention provides an MEMS carrier, comprising: a core board having a first surface and an opposite second surface, a circuit layer formed on the first surface and having a plurality of conductive pads, and a through hole formed through the first and the second surfaces; a carrier layer formed on the second surface of the core board and covering an end of the through hole; a patterned metal layer formed on a portion of the carrier layer that covers the end of the through hole; a solder mask layer formed on the first surface of the core board and the circuit layer, and having a plurality of openings for exposing the conductive pads; and a shielding metal layer formed in the through hole for covering the patterned metal layer and the portion of the carrier layer that covers the end of the through hole.

The present invention further provides a method of fabricating an MEMS carrier, comprising the stages of: providing a core board having a first surface and an opposite second surface, and a circuit layer formed on the first surface; forming in the core board a through hole passing through the first and the second surfaces; forming on the second surface of the core board a carrier layer that covers an end of the through hole; formin a patterned metal layer on the carrier layer in the through hole; forming a solder mask layer on the first surface of the core board and the circuit layer; forming a plurality of openings in the solder mask layer for exposing a portion of the circuit layer, for the exposed portion of the circuit layer to serve as conductive pads; and forming a shielding metal layer in the through hole for covering the patterned metal layer and the portion of the carrier layer that covers the end of the through hole.

In an embodiment of the present invention, the shielding metal layer is formed by the following steps of: forming a conductive seed-layer on the solder mask layer, the conductive pads, the sidewall of the through hole, the patterned metal layer, and the portion of the carrier layer that covers the end of the through hole; forming a resist layer on the conductive seed-layer; forming an open area in the resist layer for exposing the conductive seed-layer on the sidewalls of the through hole, the patterned metal layer, and the portion of the carrier layer that covers the end of the through hole; forming the shielding metal layer on the exposed conductive seed-layer; and removing the resist layer and the conductive seed-layer covered thereby.

In an embodiment of the present invention, the conductive pads comprise wire bonding pads and ball planting pads.

In an embodiment of the present invention, the method further comprises forming on the second surface of the core board an adhering layer for adhering the carrier layer to the second surface of the core board via the adhering layer.

In an embodiment of the present invention, the carrier layer further comprises a bonding metal layer for attaching the carrier layer to the second surface of the core board via the bonding metal layer, and the bonding metal layer extends to a surface of the portion of the carrier layer that covers the end of the through hole.

In an embodiment of the present invention, the method further comprises forming a surface treatment layer on the conductive pads and the shielding metal layer, and the surface treatment layer is formed by using freedom chemical plating nickel/gold, Electroless Nickel Immersion Gold (ENIG), Electroless Nickel Electroless Palladium Immersion Gold (ENEPIG), Immersion Tin, or Organic Solderability Preservative (OSP).

Accordingly, the MEMS carrier of the present invention and method of fabricating the same, through the formation of the patterned metal layer on the carrier layer, an MEMS and ASIC are allowed to be mounted on the patterned metal layer and the carrier layer. As compared with the prior art, there is no need in the present invention to use a circuit board. Therefore, the overall structure has a reduced height, and is more advantageous in the miniaturization of electronic products.

Furthermore, since the MEMS is allocated on the patterned metal layer, the acoustic hole is thus located under the MEMS. As a result, a path of signal received by the MEMS is shortened, and the signal stability and transmission speed are enhanced.

### BRIEF DESCRIPTION OF DRAWINGS

The invention can be more fully understood by reading the following detailed description of the preferred embodiments, with reference made to the accompanying drawings, wherein:

FIGS. 1A through 1E are cross-sectional diagrams depicting a method of disposing a cover component on an MEMS device according to the prior art;

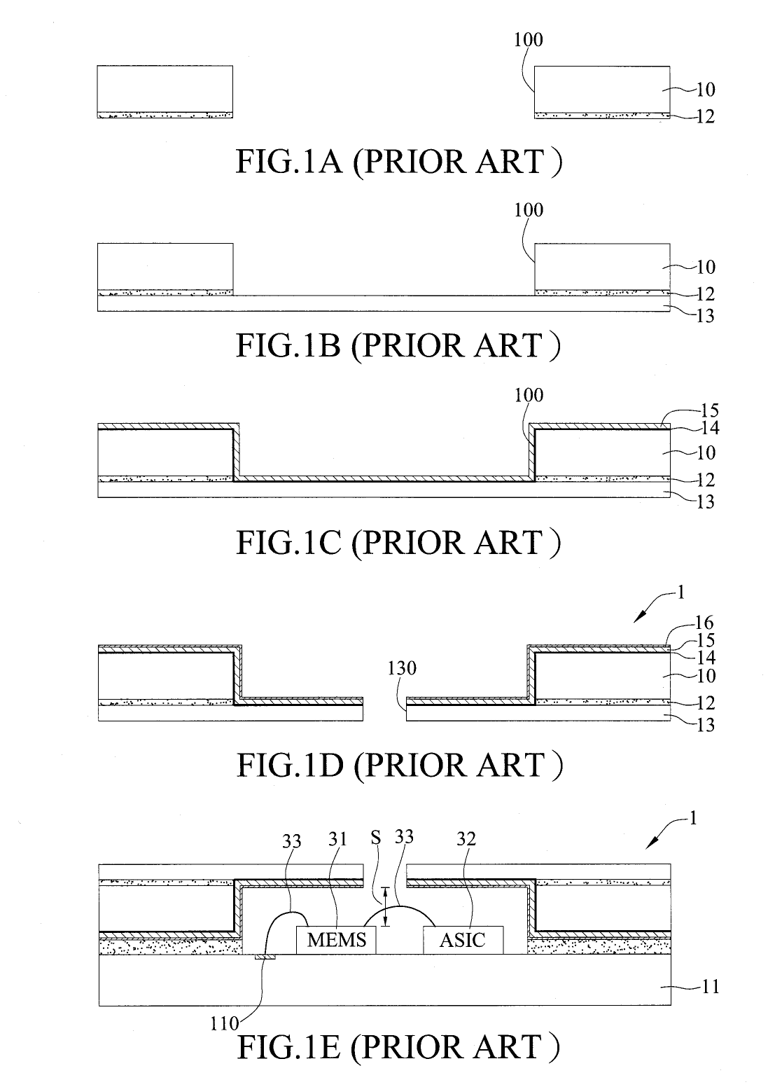

FIGS. 2A through 2I are cross-sectional diagram depicting an MEMS carrier and a method of fabricating the same according to the present invention;

FIGS. 2D′ and 2D″ are two different embodiments of FIG. 2D;

FIG. 2E′ is a top view of FIG. 2E, and FIG. 2E″ is another embodiment of FIG. 2E′;

FIGS. 2I′ and 2I″ are two different embodiments of FIG. 2I; and

FIGS. 3, 3′ and 3″ are cross-sectional diagrams depicting different embodiments of mounting an MEMS and semiconductor component on the MEMS carrier according to the present invention.

### DETAILED DESCRIPTION OF PREFERRED EMBODIMENTS

The following illustrative embodiments are provided to illustrate the disclosure of the present invention; those in the art can apparently understand these and other advantages and effects after reading the disclosure of this specification. The present invention can also be performed or applied by other different embodiments. The details of the specification may be on the basis of different points and applications, and numerous modifications and variations can be devised without departing from the spirit of the present invention.

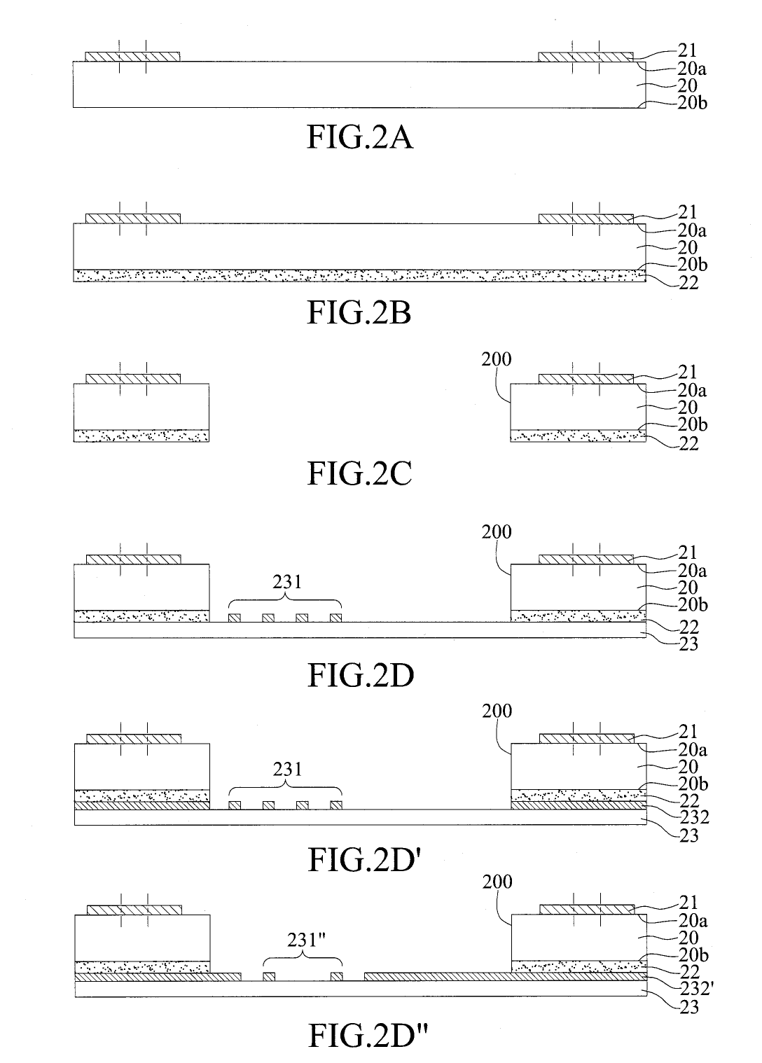

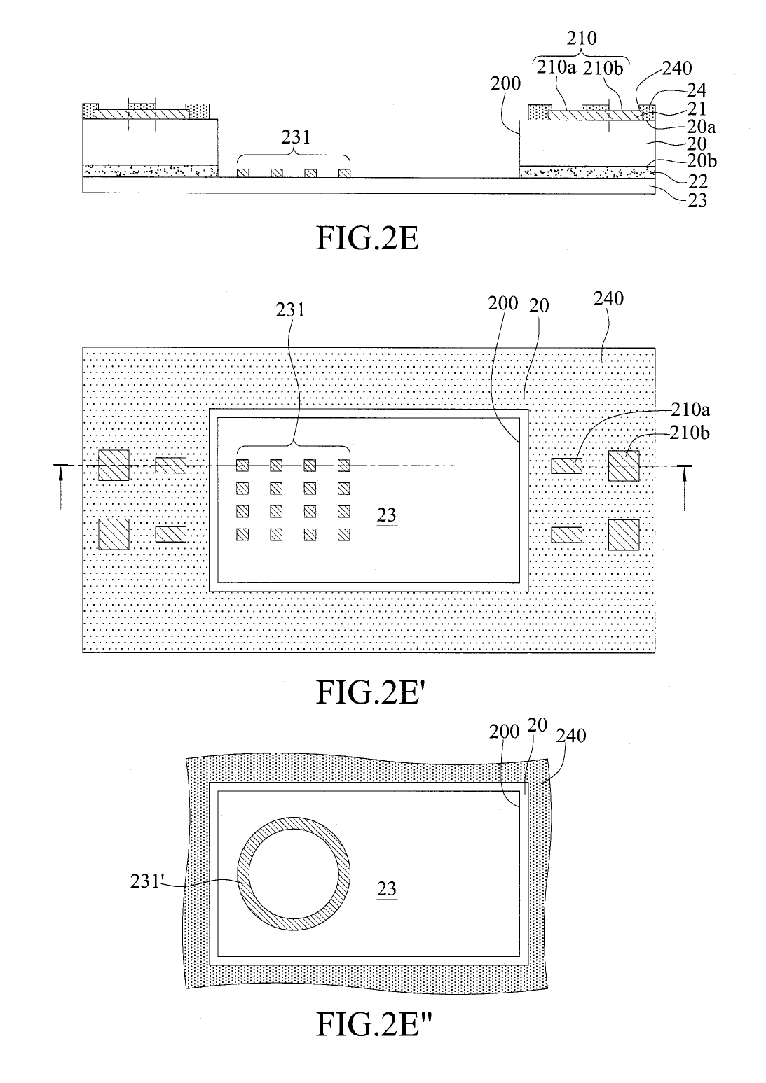

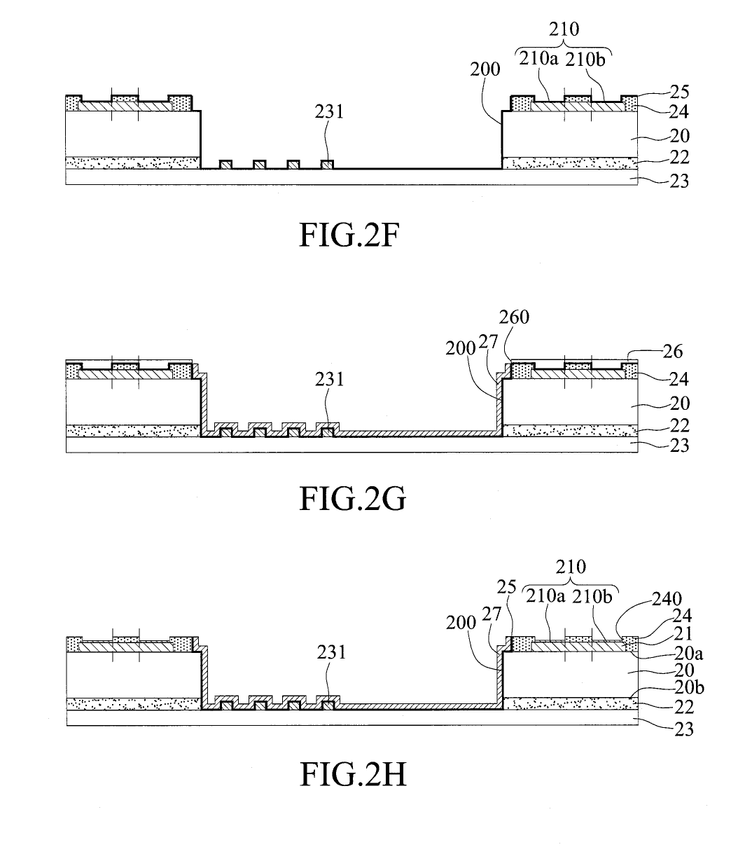

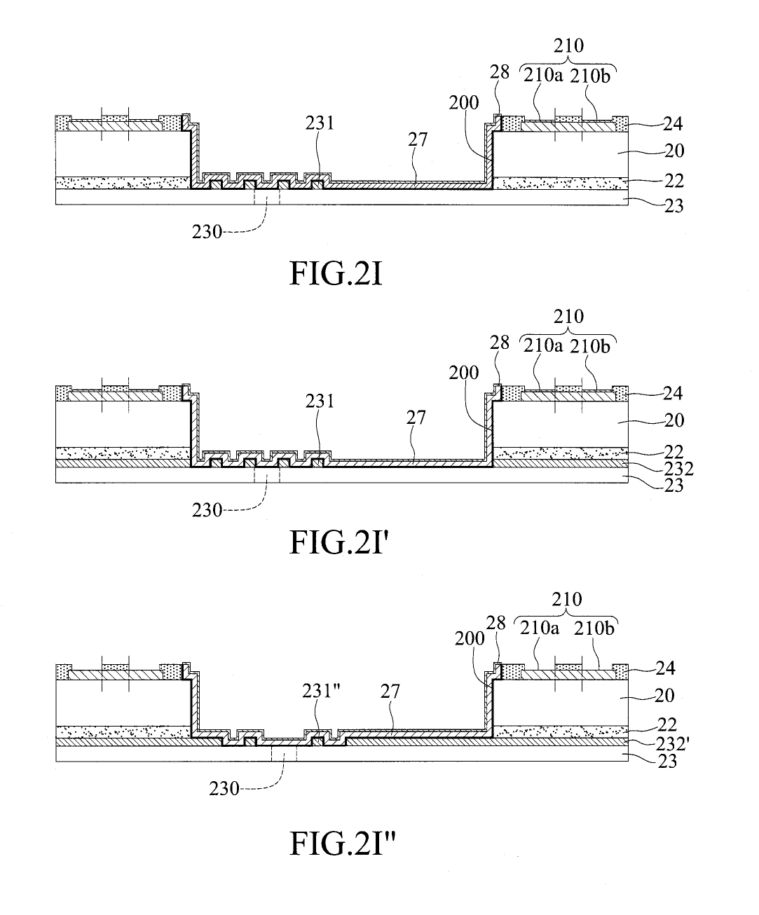

Referring now to FIGS. 2A through 2I, a method of fabricating an MEMS carrier according to the present invention is illustrated.

As shown in FIG. 2A, a core board 20 is provided that has a first surface 20a and an opposite second surface 20b, and a circuit layer 21 is formed on the first surface 20a.

As shown in FIG. 2B, an adhering layer 22 is formed on the second surface 20b of the core board 20.

As shown in FIG. 2C, on the core board 20 and the adhering layer 22 at least one through hole 200 is formed that passes through the adhering layer 22, the first surface 20a, and the second surface 20b.

As shown in FIG. 2D, a carrier layer 23 is bonded onto the second surface 20b of the core board 20 via the adhering layer 22, and the carrier layer 23 covers an end of the through hole 200. Moreover, a patterned metal layer 231 is formed on a portion of the carrier layer 23 that covers the end of the through hole 200.

As shown in FIG. 2D′, at the same time of forming the patterned metal layer 231 on the carrier layer 23, a bonding metal layer 232 is formed for attaching the carrier layer 23 to the second surface 20b of the core board 20 via the adhering layer 22.

In another embodiment, the bonding metal layer 232′ can extend to a surface of the portion of the carrier layer 23 that covers the end of the through hole 200, and a different patterned metal layer 231″ is formed, as shown in FIG. 2D″.

As shown in FIGS. 2E and 2E′, a solder mask layer 24 is formed on the first surface 20a of the core board 20 and the circuit layer 21, and a plurality of openings 240 are formed in the solder mask layer 24 for exposing a part of the circuit layer 21, thereby allowing the exposed part of the circuit layer 21 to serve as conductive pads 210. In an embodiment of the present invention, the conductive pads comprise wire bonding pads 210a and ball implanting pads 210b.

As shown in FIG. 2E″, the patterned metal layer 231′ formed on the carrier layer 23 is ring-shaped. However, there is no specific restriction on the pattern of the patterned metal layer, as design of the pattern depends on demands.

As shown in FIG. 2F, a conductive seed-layer 25 is formed on the solder mask layer 24, the conductive pads 210, a sidewall of the through cavity 200, the patterned metal layer 231, and the portion of the carrier layer 23 that covers the end of the through hole 200.

As shown in FIG. 2G, a resist layer 26 is formed on the conductive seed-layer 25, and an open area 260 is formed in the resist layer 26 for exposing the conductive seed-layer 25 on the sidewall of the through hole 200, the patterned metal layer 231, and the portion of the carrier layer 23 that covers the end of the through hole 200. A shielding metal layer 27 is formed on the exposed conductive seed-layer 25 by electroplating.

As shown in FIG. 2H, the resist layer 26 and the conductive seed-layer 25 covered thereby are removed to expose the solder mask layer 24 and the conductive pads 210.

As shown in FIG. 21, a surface treatment layer 28 is formed on the conductive pads 210 and the shielding metal layer 27. In an embodiment of the present invention, the surface treatment layer is formed by using freedom chemical plating nickel/gold, Electroless Nickel Immersion Gold (ENIG), Electroless Nickel Electroless Palladium Immersion Gold (ENEPIG), Immersion Tin, or Organic Solderability Preservative (OSP).

FIG. 2I′ depicts a continuing fabrication structure of the structure illustrated in FIG. 2D′, and FIG. 2I″ depicts a continuing fabrication structure of the structure illustrated in FIG. 2D″.

In an embodiment of the present invention, an acoustic hole 230 is further formed in the carrier layer 23 passing therethrough for enabling the carrier layer 23 to carry out multi-functional operations.

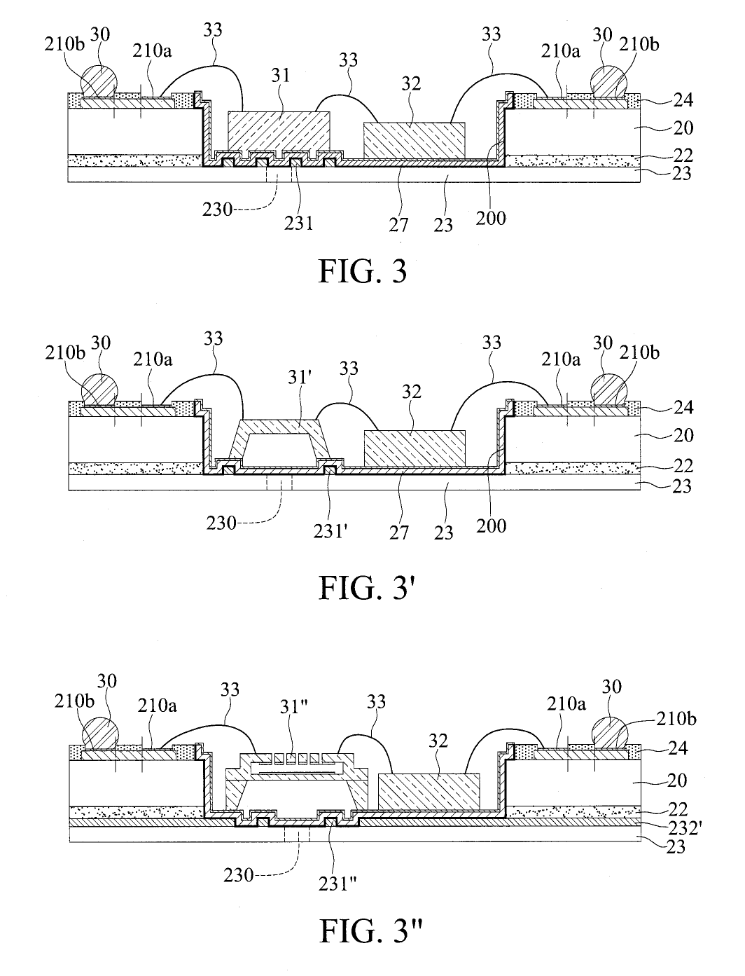

Referring to FIG. 3, an embodiment of the present invention using an MEMS carrier as shown in FIG. 21 is illustrated. As shown, a solder ball 30 is implanted on each of the ball implanting pads 210b, and then an MEMS component 31 is mounted on the patterned metal layer 231 in the through hole 200. The MEMS component 31 is electrically connected to the wire bonding pad 210a via conductive wires 33. In an embodiment of the present invention, a semiconductor component such as an application specific integrated chip (ASIC) 32 is further mounted on the carrier layer 23 in the through hole 200, and the ASIC 32 is electrically connected to the MEMS component 31 and the wire bonding pad 210a via conductive wires 33. A carrier structure is thus fabricated.

Referring to FIG. 3′, an MEMS carrier may also be fabricated from a continuing fabrication of the patterned metal layer 231′ of FIG. 2E″, and then the MEMS carrier is applied to mount a sound-controlled MEMS 31′ on the patterned metal layer 231′ in the through hole 200 thereof. Another carrier structure is thus fabricated.

In another embodiment of the present invention, by using a MEMS carrier of FIG. 2I″, a sound-controlled MEMS component 31″ is mounted on the patterned metal layer 231″ in the through hole 200, and yet another carrier structure is thus fabricated, as shown in FIG. 3″.

The MEMS carrier of the present invention comprises not only the shielding metal layer 27 but also the patterned metal layers 231, 231′ and 231″, and is capable of allocating the MEMS component 31 and the ASIC 32 on the patterned metal layers 231, 231′, and 231″ and the carrier layer 23. Accordingly, there is no need of the core of a circuit board as in the prior art, thereby efficiently reducing height of the overall structure, and being advantageous in miniaturization of electric products.

Furthermore, since the MEMS component 31 is disposed on the patterned metal layer 231, 231′, and 231″, the acoustic hole 230 is thus located under the MEMS component 31, thereby shortening path of signal received by the MEMS component 31, and efficiently enhancing signal stability and transmission speed.

The present invention further provides an MEMS carrier comprising: a core board 20 having a first surface 20a and an opposite second surface 20b, a circuit layer 21 formed on the first surface 20a and having conductive pads 210, and at least a through hole 200 formed through the first surface 20a and the second surface 20b; a carrier layer 23 formed on the second surface 20b of the core board 20 and covering an end of the through cavity 200; a patterned metal layer 231 formed on a portion of the carrier layer 23 that covers the end of the through hole 200; a solder mask layer 24 formed on the first surface 20a of the core board 20 and the circuit layer 21, wherein the solder mask layer 24 has a plurality of openings 240 for exposing the conductive pads 210; and a shielding metal layer 27 formed on a sidewall of the through hole 200, the patterned metal layer 231, and the portion of the carrier layer 23 that covers the end of the through hole 200.

The conductive pads 210 comprise wire bonding pads 210a and ball implanting pads 210b.

In an embodiment of the present invention, the MEMS carrier further comprises an adhering layer 22 disposed between the second surface 20b of the core board 20 and the carrier layer 23.

The MEMS carrier layer 23 further comprises a bonding metal layer 232 for attaching the carrier layer 23 to the second surface 20b of the core board 20.

The MEMS carrier further comprises a surface treatment layer 28 formed on the conductive pads 210 and the shielding metal layer 27. In an embodiment of the present invention, the surface treatment layer is formed by using freedom chemical plating nickel/gold, Electroless Nickel Immersion Gold (ENIG), Electroless Nickel Electroless Palladium Immersion Gold (ENEPIG), Immersion Tin, or Organic Solderability Preservative (OSP).

In view of the above, according to the MEMS carrier of the present invention and fabrication method of the same, by forming the patterned metal layer on the carrier layer, the MEMS component and ASIC can be mounted on the patterned metal layer and the carrier layer, there is no need to use a circuit board, thereby reducing the height of overall structure and being more advantageous in the miniaturization of electronic products.

Furthermore, since the MEMS component is disposed on the patterned metal layer, the acoustic hole thus is located under the MEMS component, thereby shortening path of signal received by the MEMS component, and enhancing signal stability and transmission speed.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A microelectromechanical system (MEMS) carrier, comprising:
a core board having a first surface and an opposite second surface, a circuit layer formed on the first surface and having a plurality of conductive pads, and at least a through hole formed through the first and the second surfaces;
a carrier layer disposed on the second surface of the core board and covering an end of the at least a through hole;
a patterned metal layer formed on a portion of the carrier layer that covers the end of the at least a through hole;
a solder mask layer formed on the first surface of the core board and the circuit layer, wherein the solder mask layer has a plurality of openings for exposing the conductive pads; and
a shielding metal layer formed on a sidewall of the at least a through hole, and on the carrier layer and the patterned metal layer in the through hole.

2. The MEMS carrier of claim 1, wherein the conductive pads comprise wire bonding pads and ball implanting pads.

3. The MEMS carrier of claim 1, further comprising an adhering layer disposed between the second surface of the core board and the carrier layer.

4. The MEMS carrier of claim 1, wherein a bonding metal layer is further formed on the carrier layer for attaching the carrier layer to the second surface of the core board.

5. The MEMS carrier of claim 4, wherein the bonding metal layer extends to the portion of the carrier layer that covers the end of the through hole.

6. The MEMS carrier of claim 1, further comprising a surface treatment layer formed on the conductive pads and the shielding metal layer.

7. A method of fabricating a microelectromechanical system (MEMS) carrier, comprising the steps of:
providing a core board having a first surface and an opposite second surface, with a circuit layer formed on the first surface;
forming in the core board a through hole passing through the first and the second surfaces;
disposing onto the second surface of the core board a carrier layer that covers an end of the through hole, and forming a patterned metal layer on a portion of the carrier layer that covers the end of the through hole;
forming a solder mask layer on the first surface of the core board and the circuit layer, and forming a plurality of openings in the solder mask layer for exposing a portion of the circuit layer, allowing the exposed portion of the circuit layer to serve as conductive pads; and
forming a shielding metal layer on a sidewall of the through hole, the patterned metal layer, and the portion of the carrier layer that covers the end of the through hole.

8. The method of claim 7, wherein the conductive pads comprise wire bonding pads and ball implanting pads.

9. The method of claim 7, further comprising forming on the second surface of the core board an adhering layer to thereby adhere the core board to the carrier layer via the adhering layer.

10. The method of claim 7, further comprising forming on the carrier layer a bonding metal layer for attaching the carrier layer to the second surface of the core board via the bonding metal layer.

11. The method of claim 10, wherein the bonding metal layer extends to the portion of the carrier layer that covers the end of the through hole.

12. The method of claim 7, wherein the shielding metal layer is formed by the steps of:
forming a conductive seed-layer on the solder mask layer, the conductive pads, the sidewall of the through hole, the patterned metal layer, and one portion of the carrier layer that covers the end of the through hole;
forming a resist layer on the conductive seed-layer and forming an open area in the resist layer for exposing the conductive seed-layer on the sidewall of the through hole, the patterned metal layer, the portion of the carrier layer that covers the through hole;
forming the shielding metal layer on the exposed conductive seed-layer; and
removing the resist layer and the conductive seed-layer covered thereby.

13. The method of claim 7, further comprising forming a surface treatment layer on the conductive pads and the shielding metal layer.
